(19) United States
(12) Patent Application Publication
(10) Pub. No.: US 2026/0196265 A1
(43) Pub. Date: Jul. 9, 2026

(54) MEMORY DEVICE AND OPERATING METHOD OF THE MEMORY DEVICE

(71) Applicant: SK hynix Inc., Icheon-si (KR)

(72) Inventor: In Seon Yeo, Icheon-si (KR)

(21) Appl. No.: 19/283,854

(22) Filed: Jul. 29, 2025

(30) Foreign Application Priority Data
Jan. 6, 2025 (KR) 10-2025-0001682

(51) Int. Cl. G11C 13/00

(52) U.S. Cl. CPC G11C 13/004; G11C 13/0026; G11C 13/0028; G11C 13/0038

(57) ABSTRACT

A method for operating a memory device includes receiving a first read command, performing a first forward read operation for a first memory cell based on the first read command, performing a first reverse read operation if the first memory cell has not been turned on after the first forward read operation, and providing a forward compensation pulse to the first memory cell if the first memory cell has not been turned on after the first reverse read operation.

### CROSS-REFERENCE TO RELATED APPLICATION

This application claims priority under 35 U.S.C. § 119(a) to Korean Patent Application No. 10-2025-0001682, filed in the Korean Intellectual Property Office on Jan. 6, 2025, the entire contents of which are incorporated herein by reference.

### BACKGROUND

### 1. Technical Field

Embodiments relate to an integrated circuit technology and, more particularly, to a memory device and an operating method of the memory device.

### 2. Related Art

Recently, as an electronic device is reduced in size, has lower power consumption and higher performance, and is diversified, memory capable of storing information is required for various electronic devices, such as computers and portable communication devices. Accordingly, memory having various characteristics continues to be researched.

Memory that is being researched also includes memory capable of storing data by using a characteristic in which the memory switches between different resistance states depending on a voltage or current thereto. Such memory includes resistive random access memory (RRAM), phase change random access memory (PRAM), ferroelectric random access memory (FRAM), magnetic random access memory (MRAM), an E-fuse, and selector only memory (SOM).

### SUMMARY

In an embodiment, an operating method of a memory device may include receiving a first read command, performing a first forward read operation on a first memory cell based on the first read command, performing a first reverse read operation when checking that the first memory cell has not been turned on after the start of the first forward read operation, determining the first memory cell to be in a set state when checking that the first memory cell has not been turned on after the start of the first reverse read operation, and providing a forward compensation pulse to the first memory cell determined to be in the set state.

In an embodiment, a memory device may include a memory cell electrically connected between a bit line and a word line, a voltage supply circuit configured to provide a first voltage to one of the bit line and the word line and to provide a second voltage to the other of the bit line and the word line, a sense amplifier configured to generate a sensing result by checking whether the memory cell has been turned on, and a control circuit configured to perform a forward read operation on the memory cell by controlling the voltage supply circuit when receiving a read command, perform a reverse read operation on the memory cell by controlling the voltage supply circuit based on a sensing result of the forward read operation, and provide the memory cell with one of a forward compensation pulse and a reverse compensation pulse by controlling the voltage supply circuit based on a sensing result of the reverse read operation.

### BRIEF DESCRIPTION OF THE DRAWINGS

FIG. 1 is a diagram for describing a memory cell of a memory device according to an embodiment of the present disclosure.

FIGS. 2 and 3 are diagrams for describing a write operation of the memory device according to an embodiment of the present disclosure.

FIGS. 4 and 5 are diagrams for describing a read operation of the memory device according to an embodiment of the present disclosure.

FIG. 6 is a flowchart for describing an operation of the memory device according to an embodiment of the present disclosure.

FIGS. 7 to 9 are diagrams for describing operation effects of the memory device according to an embodiment of the present disclosure.

FIG. 10 is a flowchart for describing an operation of the memory device according to another embodiment of the present disclosure.

FIG. 11 is a diagram for describing operation effects of the memory device according to another embodiment of the present disclosure.

FIG. 12 is a diagram for describing components of a memory device according to an embodiment of the present disclosure.

### DETAILED DESCRIPTION

Hereinafter, embodiments according to the technical spirit of the present disclosure are described with reference to the accompanying drawings.

Embodiments of the present disclosure are related to a technology for determining a memory cell in a set state, which has a threshold voltage level raised due to a drift, by performing a forward read operation and a reverse read operation.

Embodiments of the present disclosure relates to improving the reliability and performance of non-volatile memory devices (e.g., PRAM, RRAM an MRAM) by addressing threshold voltage drift and read disturbance. Memory cells in the SET state may experience an increase in threshold voltage over time, making them harder to read. Memory cells in the RESET state, however, may experience a decrease in threshold voltage due to repeated read operations (read disturbance), leading to potential read errors.

To correctly determine whether a memory cell is in a drifted SET state or a true RESET state, a verification operation is performed that includes a forward read operation and, when necessary, a reverse read operation. Initially, a forward read operation is performed. If the cell turns on, it is classified as (or determined to be) a normal SET state. If the cell does not turn on, a reverse read operation is performed, where a memory cell affected by SET drift will turn on and a memory cell in the RESET state will remain off. This additional verification step enables accurate classification of the drifted SET cells from true RESET cells, preventing erroneous corrective actions that could worsen threshold voltage deviations.

In an embodiment, a forward compensation pulse is selectively applied to memory cells determined to be in the SET drift state to lower their elevated threshold voltage, restoring reliable read performance. Similarly, a reverse compensation pulse is applied to memory cells in the RESET state that have experienced a reduction in threshold voltage due to repeated read operations, mitigating read disturbance and ensuring stable operation.

In an embodiment, a method for operating a memory device involves performing a read operation on a memory cell to determine whether it is in a SET state or a RESET state. If the cell does not turn on during the forward read operation, a reverse read operation is performed to further verify whether the cell is experiencing threshold voltage drift or is truly in the RESET state. Based on the results of this verification process, a compensation pulse is selectively applied to correct the detected drift.

If a memory cell is in the SET state but has experienced an increase in threshold voltage due to drift, a forward compensation pulse is applied to lower the threshold voltage, restoring proper read performance. However, if a memory cell in the RESET state has undergone a reduction in threshold voltage due to repeated read operations (read disturbance), a reverse compensation pulse is applied to raise the threshold voltage, ensuring stable and reliable operation.

It is possible to improve the data storage reliability of a memory cell.

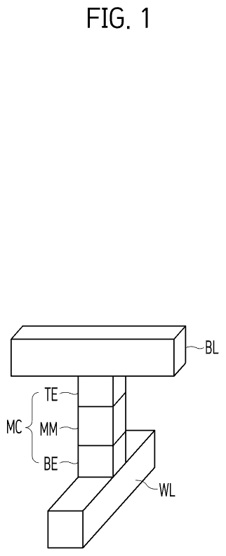

FIG. 1 is a diagram for describing a memory cell of a memory device according to an embodiment of the present disclosure.

Referring to FIG. 1, a memory cell MC of the memory device according to an embodiment of the present disclosure may be disposed between a bit line BL and a word line WL. Furthermore, the memory cell MC may be electrically coupled to the bit line BL and the word line WL. In this case, FIG. 1 illustrates that the bit line BL has been disposed over the word line WL. In another embodiment, the bit line BL may be disposed under the word line. Furthermore, the bit line BL and the word line WL may each include a conductive material.

The memory cell MC may include a first electrode TE, a memory material MM, and a second electrode BE. The memory material MM may be disposed between the first electrode TE and the second electrode BE. In this case, the first and second electrodes TE and BE may each include a conductive material. The threshold voltage level of the memory material MM may be changed depending on the direction of a current that flows through the memory material MM. The memory material MM may include a chalcogenide-series material.

For example, the second electrode BE may be formed on the word line WL. The memory material MM may be formed on the second electrode BE. The first electrode TE may be formed on the memory material MM. The bit line BL may be formed on the first electrode TE. In this case, the first electrode TE disposed at a higher location than the second electrode BE may be named a top electrode TE, and the second electrode BE disposed at a lower location than the first electrode TE may be named a bottom electrode BE, depending on the location where the first electrode TE and the second electrode BE are formed.

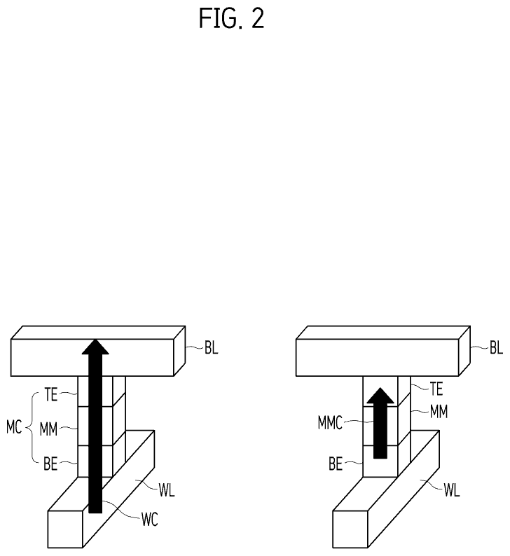

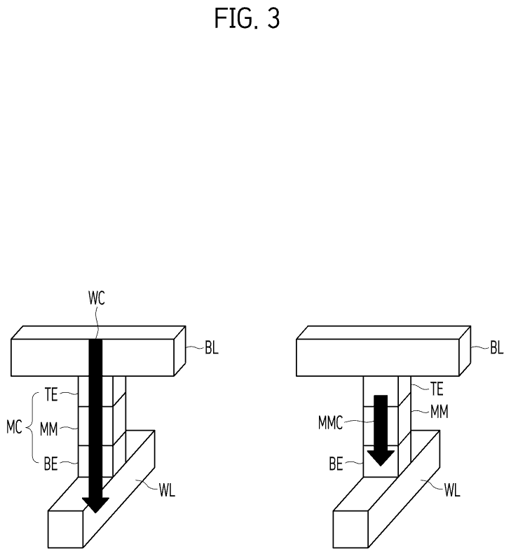

FIGS. 2 and 3 are diagrams for describing a write operation of the memory device according to an embodiment of the present disclosure.

FIG. 2 may be a diagram illustrating a write operation in which a write current WC flows from the word line WL to the bit line BL through the memory cell MC. The write operation may be an operation of providing the word line WL and the bit line BL with a voltage in which a difference between the voltage levels of the word line WL and the bit line BL is greater than a voltage level to the extent that the memory cell MC is turned on. In this case, a voltage higher than the voltage of the bit line BL may be provided to the word line WL.

The write operation may be an operation that changes a memory material characteristic MMC so that a current better flows in a first direction than in a second direction through the memory material MM. In this case, the first direction may be a direction in which the current flows from the word line WL to the bit line BL through the memory material MM. The second direction may be a direction in which the current flows from the bit line BL to the word line WL through the memory material MM.

FIG. 3 may be a diagram illustrating a write operation in which the write current WC flows from the bit line BL to the word line WL through the memory cell MC. The write operation may be an operation of providing the bit line BL and the word line WL with a voltage in which a difference between the voltage levels of the bit line BL and the word line WL is greater than a voltage level to the extent that the memory cell MC is turned on. In this case, a voltage higher than the voltage of the word line WL may be applied to the bit line BL.

The write operation may be an operation that changes the memory material characteristic MMC so that a current better flows in the second direction than in the first direction through the memory material MM. In this case, the first direction may be a direction in which the current flows from the word line WL to the bit line BL through the memory material MM. The second direction may be a direction in which the current flows from the bit line BL to the word line WL through the memory material MM.

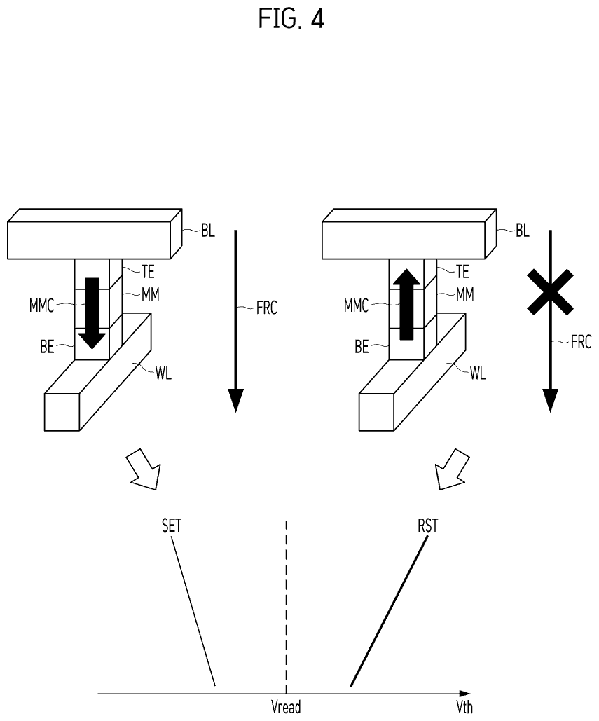

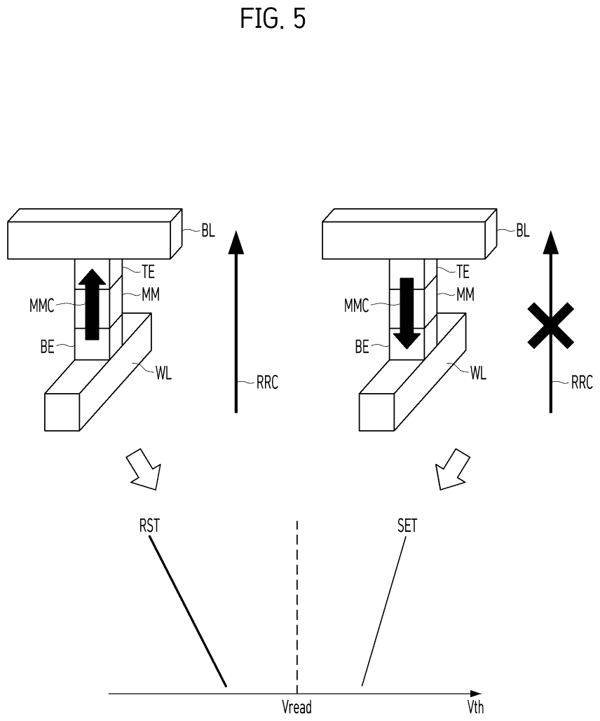

FIGS. 4 and 5 are diagrams for describing a read operation of the memory device according to an embodiment of the present disclosure.

FIG. 4 illustrates a forward read operation according to an embodiment.

Referring to FIG. 4, the forward read operation may be used to determine the state of the memory cell MC by providing the bit line BL with a voltage having a higher level than the voltage of the word line WL. In this case, the forward read operation may cause a forward read current FRC to flow in the same direction as the current direction WC after the start of the write operation illustrated in FIG. 3. Furthermore, a difference between the voltage levels of the bit line BL and the word line WL after the start of the forward read operation may correspond to the level of a read voltage Vread. The read voltage Vread may have a voltage level between the threshold voltage level of the memory cell MC according to a write operation, as described with reference to FIG. 2, and the threshold voltage level of the memory cell MC according to a write operation, as described with reference to FIG. 3.

Accordingly, when the forward read operation is performed on the memory cell MC having the memory material characteristic MMC changed as illustrated in FIG. 4 through the write operation of making the write current WC flow from the bit line BL to the word line WL as described with reference to FIG. 3, the forward read current FRC may flow from the bit line BL to the word line WL through the memory cell MC that has been turned on. At this time, the memory cell MC may be turned on because the threshold voltage level of the memory cell MC having the memory material characteristic MMC changed by a write operation, as described with reference to FIG. 3, is lower than the read voltage Vread.

When the forward read operation is performed on the memory cell MC having the memory material characteristic MMC changed as illustrated in FIG. 4 through a write operation, as described with reference to FIG. 2, the forward read current FRC might not flow. At this time, the memory cell MC might not be turned on because the threshold voltage level of the memory cell MC having the memory material characteristic MMC changed by a write operation, as described with reference to FIG. 2, is higher than the read voltage Vread. Accordingly, the forward read current FRC might not flow.

The memory cell MC having a threshold voltage having a lower level than the read voltage Vread may be said to be in a set state SET. The memory cell MC having a threshold voltage having a higher level than the read voltage Vread may be said to be in a reset state RST.

That is, the state of the memory cell MC may be changed to the set state SET through a write operation, as described with reference to FIG. 3. Furthermore, the state of the memory cell MC may be changed to the reset state RST through a write operation, as described with reference to FIG. 4. In this case, the write operation of changing the state of the memory cell MC to the set state SET may be named a set write operation. The write operation of changing the state of the memory cell MC to the reset state RST may be named a reset write operation.

FIG. 5 illustrates a diagram for describing a reverse read operation according to an embodiment.

Referring to FIG. 5, the reverse read operation may be used to determine the state of the memory cell MC by providing the word line WL with a voltage having a higher level than the voltage of the bit line BL. In this case, the reverse read operation may be an operation of making a reverse read current RRC flow in the same direction as the current direction WC after the start of the write operation illustrated in FIG. 2. Furthermore, a difference between the voltage levels of the word line WL and the bit line BL after the start of the reverse read operation may correspond to the level of the read voltage Vread. The read voltage Vread may have a voltage level between the threshold voltage level of the memory cell MC according to a write operation, as described with reference to FIG. 2, and the threshold voltage level of the memory cell MC according to a write operation, as described with reference to FIG. 3. In this case, the level of the read voltage Vread described with reference to FIG. 4 and the level of the read voltage Vread described with reference to FIG. 5 may be the same.

Accordingly, when a reverse read operation is performed on the memory cell MC having the memory material characteristic MMC changed as illustrated in FIG. 5 through the write operation of making the write current WC flow from the word line WL to the bit line BL as illustrated in FIG. 2, the reverse read current RRC may flow from the word line WL to the bit line BL through the memory cell MC that has been turned on. At this time, the memory cell MC may be turned on because the threshold voltage level of the memory cell MC having the memory material characteristic MMC changed is lower than the read voltage Vread by a write operation, as described with reference to FIG. 2.

When a reverse read operation is performed on the memory cell MC having the memory material characteristic MMC changed as illustrated in FIG. 5 through a write operation, as described with reference to FIG. 3, the reverse read current RRC might not flow. At this time, the memory cell MC might not be turned on because the threshold voltage level of the memory cell MC having the memory material characteristic MMC changed is higher than the read voltage Vread by a write operation, as described with reference to FIG. 3. Accordingly, the reverse read current RRC might not flow.

Accordingly, the memory cell MC in the reset state RST, which has been determined to have a high threshold voltage after the start of a forward read operation, may be determined to have a low threshold voltage after the start of a reverse read operation. Furthermore, the memory cell MC in the set state SET, which has been determined to have a low threshold voltage after the start of a forward read operation, may be determined to have a high threshold voltage after the start of a reverse read operation.

As a result, referring to FIGS. 4 and 5, when a read operation of making a current flow in the same direction as the write current WC after the start of a write operation is performed, the memory cell MC may be determined to have a low threshold voltage. Furthermore, when a read operation of making a current flow in a direction opposite to the direction of the write current WC after the start of a write operation is performed, the memory cell MC may be determined to have a high threshold voltage.

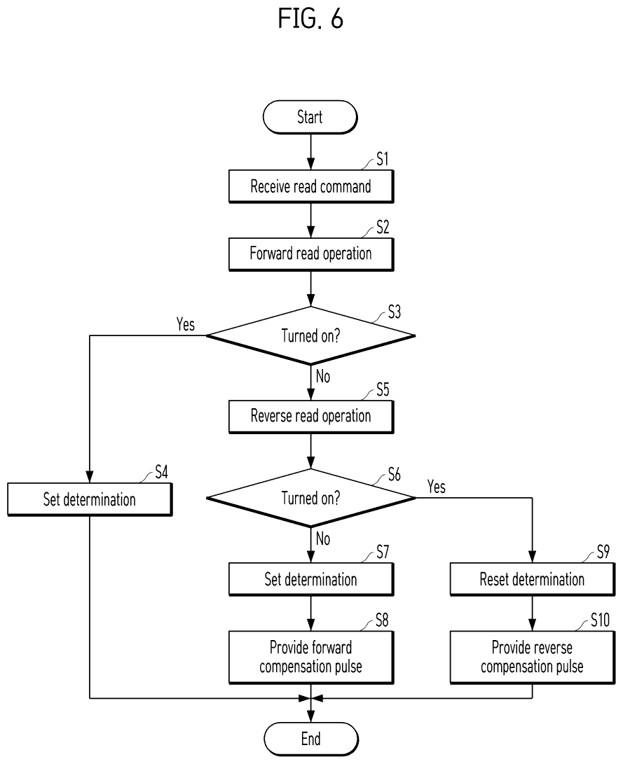

FIG. 6 is a flowchart for describing an operation of the memory device according to an embodiment of the present disclosure.

Referring to FIG. 6, an operating method of the memory device according to an embodiment of the present disclosure may include a read command-receiving operation S1, a forward read operation execution operation S2, a first turn-on check operation S3, a first set determination operation S4, a reverse read operation execution operation S5, a second turn-on check operation S6, a second set determination operation S7, a forward compensation pulse provision operation S8, a reset determination operation S9, and a reverse compensation pulse provision operation S10.

The read command-receiving operation S1 may involve the memory device receiving a read command from an external device (e.g., a controller).

The forward read operation execution operation S2 may involve performing a read operation by providing the bit line BL with a voltage having a higher level than the voltage of the word line WL.

The first turn-on check operation S3 involves checking the results of the read operation performed in the forward read operation execution operation S2 and checking whether the memory cell MC has been turned on after the start of a forward read operation.

If the memory cell MC is turned on in the first turn-on check operation S3, the first set determination operation S4 may be performed.

The first set determination operation S4 may involve determining that the memory cell MC is in the set state SET. The read operation attributable to the reception of the read command may be terminated after the first set determination operation S4.

If the memory cell MC is not turned on in the first turn-on check operation S3, the reverse read operation execution operation S5 may be performed.

The reverse read operation execution operation S5 may involve performing a read operation by providing the word line WL with a voltage having a higher level than the voltage of the bit line BL, unlike the forward read operation execution operation S2 where the bit line BL is provided with a higher voltage than the word line WL.

The second turn-on check operation S6 involves checking the results of the read operation performed in the reverse read operation execution operation S2 and checking whether the memory cell MC has been turned on after the start of the reverse read operation.

If the memory cell MC is not turned on in the second turn-on check operation S6, the second set determination operation S7 may be performed. An operating method of the memory device according to an embodiment of the present disclosure may be constructed to be terminated without performing the forward compensation pulse provision operation S8 after the second set determination operation S7. That is, the forward compensation pulse provision operation S8 may be provided as an option in the operating method of the memory device according to an embodiment of the present disclosure. Accordingly, the operating method of the memory device may be designed so that the forward compensation pulse provision operation S8 is performed after the second set determination operation S7, and may be terminated without providing the forward compensation pulse S8 after the second set determination operation S7.

The second set determination operation S7 may include an operation of determining that the memory cell MC is in the set state SET. The forward compensation pulse provision operation S8 may be performed after the second set determination operation S7.

The forward compensation pulse provision operation S8 may involve lowering the threshold voltage of the memory cell MC in the set state SET, which may have been raised due to a drift, by providing the bit line BL with a voltage having a higher level than the voltage of the word line WL. At this time, a difference between the voltage levels of the bit line BL and the word line WL in the forward compensation pulse provision operation S8 may be greater than or equal to a difference between the voltage levels of the bit line BL and the word line WL in the forward read operation execution operation S2.

When the memory cell MC is determined to be turned on in the second turn-on check operation S6, the reset determination operation S9 may be performed.

The reset determination operation S9 may involve determining that the memory cell MC is in the reset state RST.

The reverse compensation pulse provision operation S10 may be performed after the reset determination operation S9. In an embodiment, an operating method of the memory device may be designed to be terminated without performing the reverse compensation pulse provision operation S10. That is, the reverse compensation pulse provision operation S10 may be an option step. Accordingly, the operating method may execute the reverse compensation pulse provision operation S10 after the reset determination operation S9 or may terminate without performing the reverse compensation pulse provision operation S10.

The reverse compensation pulse provision operation S10 may involve raising the threshold voltage of the memory cell MC in the reset state RST, which has been lowered by repetitive forward read operations, by providing the word line WL with a voltage having a higher level than the voltage of the bit line WL. At this time, a difference between the voltage levels of the word line WL and the bit line BL in the reverse compensation pulse provision operation S10 may be greater than or equal to a difference between the voltage levels of the word line WL and the bit line BL in the reverse read operation execution operation S5.

When the set determination operation S4 of determining that the memory cell MC is in the set state SET because the turn-on of the memory cell MC is checked as the results of the forward read operation execution operation S2 and the first turn-on check operation S3 is performed, the forward compensation pulse provision operation S8 and the reverse compensation pulse provision operation S10 might not be performed.

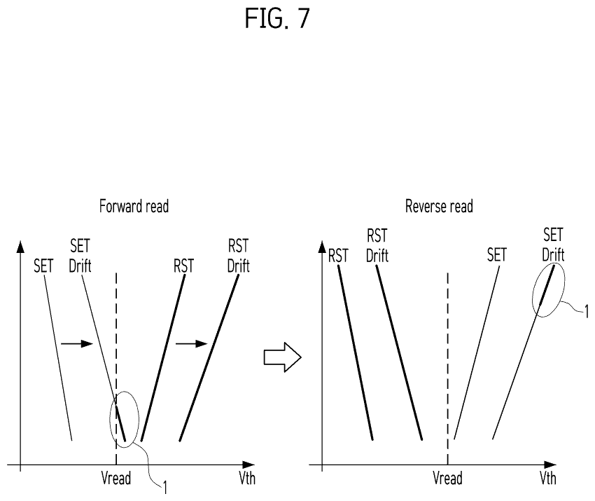

FIGS. 7 to 9 are diagrams for describing operation effects of the memory device according to an embodiment of the present disclosure.

FIG. 7 may be a diagram for describing an operation of performing a reverse read operation based on the results of a forward read operation.

The threshold voltage level of the memory cell MC included in the memory device according to an embodiment of the present disclosure may rise as time elapses. This may be referred to as a drift of the memory cell MC.

For example, the threshold voltage level of the memory cell MC in the set state SET may rise as time elapses, which may be referred to as a drifted set state SET Drift. The threshold voltage level of the memory cell MC in the reset state RST may rise as time elapses, which may be referred to as a drifted reset state RST Drift.

After the start of a forward read operation, the threshold voltage level of the memory cell MC in the drifted set state SET Drift may be higher than a difference between the levels of voltages applied to both ends of the memory cell MC, that is, a difference between the voltage levels of the bit line BL and the word line WL. That is, a part 1 in which the threshold voltage level of the memory cell MC in the drifted set state SET Drift is higher than the read voltage Vread may be present after the start of a forward read operation.

As a result, after initiating the forward read operation, the memory cell MC in the set state SET is expected to be turned on. However, the memory MC may fail to turn on if the threshold voltage level of the memory cell MC has increased due to drift.

Accordingly, if the memory cell MC is not turned on after the forward read operation S2, a reverse read operation S5 may be performed.

As described above, a reverse read operation may involve applying a voltage of the same magnitude as the read voltage Vread used in a forward read operation but causing the current to flow in the opposite direction compared to when the memory cell MC is turned on. For example, in a forward read operation, the bit line BL is provided with a voltage having a higher level than that of the word line WL. In the reverse read operation, the word line WL is provided with a voltage having a higher level than that of the bit line BL.

The threshold voltage level of the memory cell MC in the set state SET, which is lower than the threshold voltage of the memory cell MC in the reset state RST, after the start of a forward read operation may be higher than the threshold voltage level of the memory cell MC in the reset state RST after the start of a reverse read operation.

Accordingly, the memory cell MC in the normal set state SET may be turned on after the start of a forward read operation, and the memory cell MC in the normal set state SET may be turned off after the start of a reverse read operation. Furthermore, the memory cell MC in the normal reset state RST may be turned on after the start of a forward read operation, and the memory cell MC in the normal reset state RST may be turned on after the start of a reverse read operation.

Although the memory cell MC is not turned on after the start of a forward read operation due to a drift of the memory cell MC in the set state SET, the memory cell MC may be determine to be in the set state SET when the turn-on of the memory cell MC is checked by performing a reverse read operation.

A memory device according to an embodiment of the present disclosure may determine the state of a memory cell, which may be determined abnormally, normally by performing a forward read operation and performing a reverse read operation based on the results of the forward read operation. Accordingly, the memory device according to an embodiment of the present disclosure can improve the reliability of a read operation.

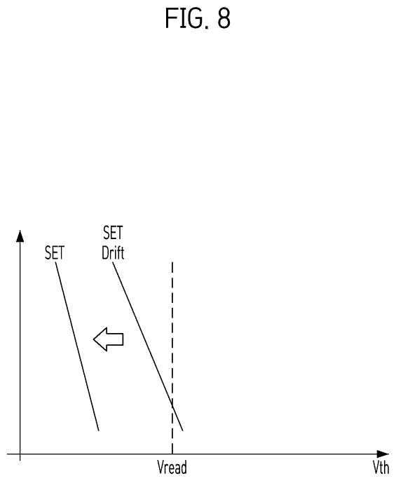

FIG. 8 may be a diagram for describing an operation of providing the memory cell MC with a forward compensation pulse, after the memory cell MC is determined to be in the set state SET, based on the results of a reverse read operation after a forward read operation.

Referring to FIG. 8, when a forward compensation pulse is provided to the memory cell MC in the set state SET Drift, which has a threshold voltage level raised due to a drift, the threshold voltage of the memory cell MC may be lowered. In this case, an operation of providing the forward compensation pulse is an operation of providing different voltages to both ends of the memory cell MC for a set time, and may be an operation of making a current flow in the same direction as the direction of a current after the start of a forward read operation and the direction of a current after the start of a set write operation. For example, an operation of providing the forward compensation pulse may be an operation of providing a higher voltage to the bit line BL than to the word line WL. At this time, a difference between the voltage levels of the bit line BL and the word line WL may be equal to or greater than the level of the read voltage Vread.

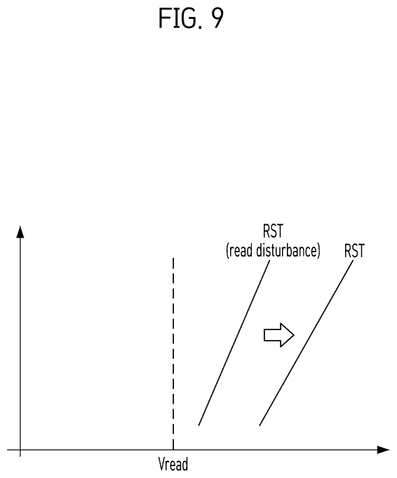

FIG. 9 may be a diagram for describing an operation of providing the memory cell MC with a reverse compensation pulse after the memory cell MC is determined to be in the reset state RST based on the results of a reverse read operation after a forward read operation.

Referring to FIG. 9, when a reverse compensation pulse is provided to the memory cell MC in the reset state RST (read disturbance), which has a threshold voltage level lowered due to repetitive forward read operations, the threshold voltage of the memory cell MC may be raised. In this case, the lowering of the threshold voltage level of the memory cell MC in the reset state RST due to repetitive forward read operations may be named read disturbance. An operation of providing a reverse compensation pulse is an operation of providing different voltages to both ends of the memory cell MC for a set time, and may be an operation of making a current flow in the same direction as the direction of a current after the start of a reverse read operation and the direction of a current after the start of a reset write operation. For example, an operation of providing a reverse compensation pulse may be an operation of providing a higher voltage to the word line WL than to the bit line BL. At this time, a difference between the voltage levels of the word line WL and the bit line BL may be equal to or greater than the level of the read voltage Vread.

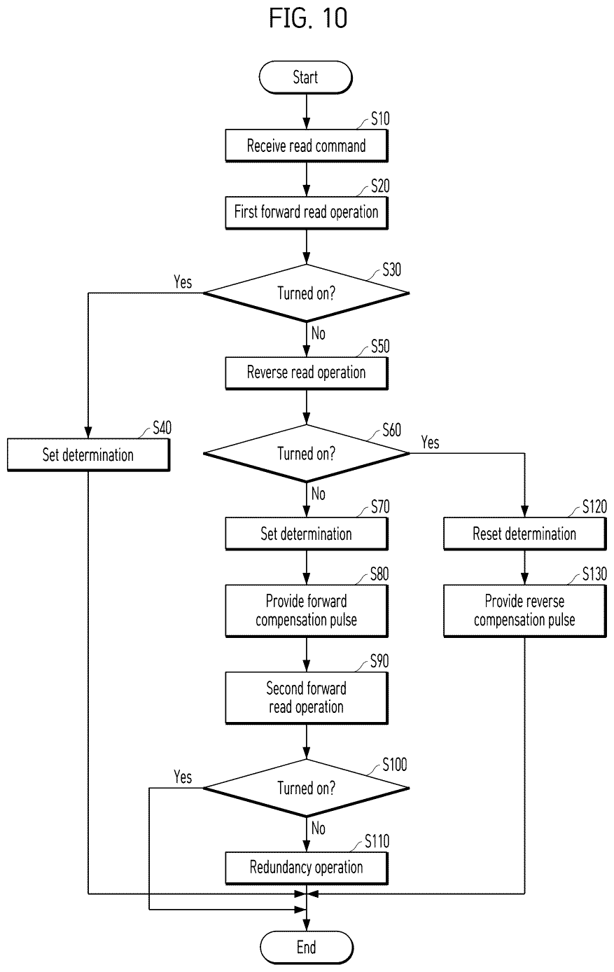

FIG. 10 is a flowchart for describing an operation of the memory device according to another embodiment of the present disclosure.

Referring to FIG. 10, the operating method of the memory device according to another embodiment of the present disclosure may include a read command-receiving operation S10, a first forward read operation execution operation S20, a first turn-on check operation S30, a first set determination operation S40, a reverse read operation execution operation S50, a second turn-on check operation S60, a second set determination operation S70, a forward compensation pulse provision operation S80, a second forward read operation execution operation S90, a third turn-on check operation S100, a redundancy operation execution operation S110, a reset determination operation S120 and a reverse compensation pulse provision operation S130.

The read command-receiving operation S10 may include an operation of the memory device receiving a read command from an external device (e.g., a controller).

The first forward read operation execution operation S20 may include an operation of performing a read operation by providing the bit line BL with a voltage having a higher level than the voltage of the word line WL.

The first turn-on check operation S30 is an operation of checking the results of the read operation performed in the first forward read operation execution operation S20, and may include an operation of checking whether the memory cell MC has been turned on after the start of a forward read operation.

When the turn-on of the memory cell MC is checked (Yes) in the first turn-on check operation S30, the first set determination operation S40 may be performed.

The first set determination operation S40 may include an operation of determining that the memory cell MC is in the set state SET. After the first set determination operation S40, the read operation attributable to the reception of the read command may be terminated.

When the turn-on of the memory cell MC is not checked (No) in the first turn-on check operation S30, the reverse read operation execution operation S50 may be performed.

The reverse read operation execution operation S50 may include an operation of performing a read operation by providing the word line WL with a voltage having a higher level than the voltage of the bit line BL, unlike the forward read operation execution operation S20.

The second turn-on check operation S60 is an operation of checking the results of the read operation performed in the reverse read operation execution operation S50, and may include an operation of checking whether the memory cell MC has been turned on after the start of the reverse read operation.

When the turn-on of the memory cell MC is not checked (No) in the second turn-on check operation S60, the second set determination operation S70 may be performed.

The second set determination operation S70 may include an operation of determining that the memory cell MC is in the set state SET. After the second set determination operation S70, the forward compensation pulse provision operation S80 may be performed.

The forward compensation pulse provision operation S80 may be an operation of lowering the threshold voltage of the memory cell MC in the set state SET, which has been raised due to a drift, by providing the bit line BL with a voltage having a higher level than the voltage of the word line WL. At this time, a difference between the voltage levels of the bit line BL and the word line WL in the forward compensation pulse provision operation S80 may be greater than or equal to a difference between the voltage levels of the bit line BL and the word line WL in the forward read operation execution operation S20.

After the forward compensation pulse provision operation S80 is performed, the second forward read operation execution operation S90 may be performed.

The second forward read operation execution operation S90 may include an operation of performing a read operation by providing the bit line BL with a voltage having a higher level than the voltage of the word line WL, like the first forward read operation execution operation S20.

The third turn-on check operation S100 is an operation of checking the results of the read operation performed in the second forward read operation execution operation S90, and may include an operation of checking whether the memory cell MC has been turned on after the start of the forward read operation.

When the turn-on of the memory cell MC is checked (Yes) in the third turn-on check operation S100, the operation of the memory device according to another embodiment of the present disclosure may be terminated.

When the turn-on of the memory cell MC is not checked (No) in the third turn-on check operation S100, the redundancy operation execution operation S110 may be performed.

The redundancy operation execution operation S110 may include an operation of determining the memory cell MC on which the second forward read operation execution operation S90 has been performed to be a failed memory cell and performing a redundancy operation of substituting the failed memory cell with another memory cell. In this case, the first forward read operation execution operation S20, the reverse read operation execution operation S50, and the second forward read operation execution operation S90 may be operations of reading the same memory cell MC.

When the turn-on of the memory cell MC is checked (Yes) in the second turn-on check operation S60, the reset determination operation S120 may be performed.

The reset determination operation S120 may include an operation of determining that the memory cell MC is in the reset state RST.

After the reset determination operation S120, the reverse compensation pulse provision operation S130 may be performed. The operating method of the memory device according to another embodiment of the present disclosure may be constructed to be terminated without performing the reverse compensation pulse provision operation S130 after the reset determination operation S120. That is, the reverse compensation pulse provision operation S130 is provided as an option in the operating method of the memory device according to another embodiment of the present disclosure. Accordingly, the operating method of the memory device according to another embodiment of the present disclosure may be constructed so that the reverse compensation pulse provision operation S130 is performed after the reset determination operation S120, and may be terminated without performing the reverse compensation pulse provision operation S130 after the reset determination operation S120.

The reverse compensation pulse provision operation S130 may be an operation of raising the threshold voltage of the memory cell MC in the reset state RST, which has been lowered due to repetitive forward read operations, by providing the word line WL with a voltage having a higher level than the voltage of the bit line WL. At this time, a difference between the voltage levels of the word line WL and the bit line BL in the reverse compensation pulse provision operation S130 may be greater than or equal to a difference between the voltage levels of the word line WL and the bit line BL in the reverse read operation execution operation S50.

In this case, each of the operating methods of the memory device, which have been described with reference to FIGS. 10 and 6, may be terminated when a memory cell is determined to be in the set state based on the results of a forward read operation according to one read command. Furthermore, each of the operating methods described with reference to FIGS. 10 and 6 may be terminated by providing a forward compensation pulse to a memory cell determined to be in the set state based on the results of a forward read operation and a reverse read operation according to another read command. Each of the operating methods described with reference to FIGS. 10 and 6 may be terminated by providing a reverse compensation pulse to a memory cell determined to be in the reset state based on the results of a forward read operation and a reverse read operation according to still another read command. The memory cell may be determined to be in the set state based on the results of a forward read operation and a reverse read operation according to still another read command, and may be provided with a forward compensation pulse. Thereafter, an additional forward read operation may be performed, and a redundancy operation of substituting the memory cell with another memory cell based on the results of the additional read operation may be performed.

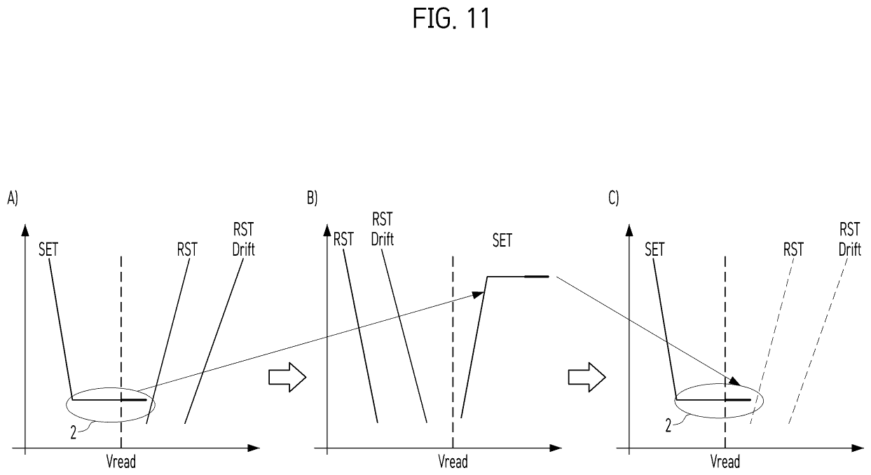

FIG. 11 is a diagram for describing operation effects of the memory device according to another embodiment of the present disclosure.

FIG. 11 may be a diagram for describing an operation of performing a forward read operation after a forward read operation A and a reverse read operation B are consecutively performed.

Referring to FIG. 11, the memory cell MC is a failed memory cell, and may be a memory cell MC in the set state SET, which includes an ideal distribution 2. The threshold voltage level of the memory cell MC in the set state SET, including the ideal distribution 2, may be higher than the level of the read voltage Vread.

FIG. 11(A) may illustrate a first forward read operation for the memory cell MC in the set state SET, which includes the ideal distribution 2. The memory cell MC may be determined to have not been turned on in a forward read operation because the threshold voltage level of the memory cell MC in the set state SET, including the ideal distribution 2, is higher than the level of the read voltage Vread.

FIG. 11(B) may illustrate a reverse read operation for the memory cell MC that has been determined to have not been turned on in the forward read operation of FIG. 11(A). The memory cell MC may be determined to have not been turned on in the reverse read operation because the threshold voltage level of the memory cell MC in the set state SET is higher than the level of the read voltage Vread in the reverse read operation. Accordingly, the memory cell MC may be determined to be in the set state SET in which the threshold voltage level of the memory cell MC has risen due to a drift. In this case, the threshold voltage level of the memory cell MC, which has risen due to the drift, may be lowered by providing the memory cell MC with a forward compensation pulse.

However, the threshold voltage level of the memory cell MC in the set state SET, including the ideal distribution 2, might not be lowered although the forward compensation pulse is provided to the memory cell MC.

FIG. 11(C) may illustrate an operation of performing a forward read operation again after the reverse read operation and the operation of providing the forward compensation pulse were performed. The threshold voltage level of the memory cell MC may be higher than the level of the read voltage Vread even in a read operation that has been performed on the memory cell MC again because the ideal distribution 2 is not changed although the forward compensation pulse is provided to the memory cell MC including the ideal distribution 2 as described above. Accordingly, if the memory cell MC is checked to have not been turned on based on the results of a forward read operation, which has been performed on the memory cell MC provided with the forward compensation pulse again, the memory cell MC may be determined to be a failed memory cell. Furthermore, the memory cell MC determined to be the failed memory cell may be substituted with another memory cell. In this case, an operation of substituting the failed memory cell with another memory cell because the memory cell MC is determined to be the failed memory cell may be named a redundancy operation.

As described above, according to the operation of the memory device according to another embodiment of the present disclosure, a normal memory cell and a failed memory cell can be distinguished by performing a forward read operation again after a forward compensation pulse is provided based on the results of a forward read operation and a reverse read operation performed.

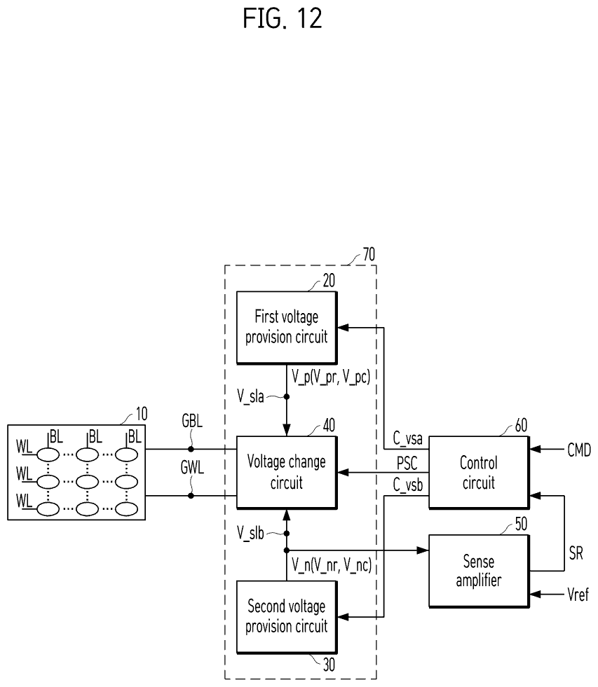

FIG. 12 is a diagram for describing components of a memory device according to an embodiment of the present disclosure.

Referring to FIG. 12, the memory device according to an embodiment of the present disclosure may include a cell array 10, a first voltage provision circuit 20, a second voltage provision circuit 30, a voltage change circuit 40, a sense amplifier 50, and a control circuit 60.

The cell array 10 may include at least one memory cell MC that is electrically connected between a bit line BL and a word line WL. In this case, the bit line BL may be electrically connected to a global bit line GBL. The word line WL may be electrically connected to a global word line GWL. For example, the bit line BL may be electrically connected to or separated from the global bit line GBL based on an address (not illustrated). Furthermore, the word line WL may also be electrically connected to or separated from the global word line GWL based on an address (not illustrated).

The first voltage provision circuit 20 may provide the voltage change circuit 40 with a first voltage V_p through a first voltage line V_sla. In this case, the first voltage V_p may include a first read operation voltage V_pr and a first compensation operation voltage V_pc. The first voltage provision circuit 20 may provide the voltage change circuit 40 with one of the first read operation voltage V_pr and the first compensation operation voltage V_pc as the first voltage V_p through the first voltage line V_sla based on a first voltage level control signal C_vsa.

The second voltage provision circuit 30 may provide the polarity change circuit 40 with a second voltage V_n through a second voltage line V_slb. In this case, the first voltage V_p may have a higher level than the second voltage V_n. The first voltage V_p may be a positive voltage, and the second voltage V_n may be a negative voltage. Furthermore, the second voltage V_n may include a second read operation voltage V_nr and a second compensation operation voltage V_nc. The second voltage provision circuit 30 may provide the voltage change circuit 40 with one of the second read operation voltage V_nr and the second compensation operation voltage V_nc as the second voltage V_n through the second voltage line V_slb based on a second voltage level control signal C_vsb.

In this case, a difference between the levels of the first read operation voltage V_pr and the second read operation voltage V_nr may be smaller than or equal to a difference between the levels of the first compensation operation voltage V_pc and the second compensation operation voltage V_nc. Furthermore, the first compensation operation voltage V_pc may be a voltage having a higher level than the first read operation voltage V_pr. The second compensation operation voltage V_nc may be a voltage having a lower level than the second read operation voltage V_nr. Furthermore, the first read operation voltage V_pr and the first compensation operation voltage V_pc may each be a voltage having a higher level than each of the second read operation voltage V_nr and the second compensation operation voltage V_nc.

The voltage change circuit 40 may provide the first voltage V_p to one of the global bit line GBL and the global word line GWL based on a voltage switching control signal PSC, and may provide the second voltage V_n to the other of the global bit line GBL and the global word line GWL. For example, when providing the first voltage V_p to the global bit line GBL based on the voltage switching control signal PSC, the voltage change circuit 40 may provide the second voltage V_n to the global word line GWL. Furthermore, when providing the first voltage V_p to the global word line GWL based on the voltage switching control signal PSC, the voltage change circuit 40 may provide the second voltage V_n to the global bit line GBL.

The sense amplifier 50 may determine whether the memory cell MC has been turned on. For example, the sense amplifier 50 may determine whether the memory cell MC has been turned on by comparing the voltage level of the second voltage line V_slb and a reference voltage Vref after the start of a forward read operation and a reverse read operation, and may output the results of the determination as a sensing result SR. More specifically, after the start of a forward read operation, the sense amplifier 50 may output the sensing result SR (e.g., a high level) indicating that the memory cell MC has been turned on when the voltage level of the second voltage line V_slb is higher than the level of the reference voltage Vref. After the start of a reverse read operation, the sense amplifier 50 may output the sensing result SR (e.g., a low level) indicating that the memory cell MC has been turned off when the voltage level of the second voltage line V_slb is lower than the level of the reference voltage Vref.

The control circuit 60 may generate the first and second voltage level control signals C_vsa and C_vsb and the voltage switching control signal PSC, based on a command CMD and the sensing result SR. Furthermore, the control circuit 60 may provide the first and second voltage level control signals C_vsa and C_vsb to the first and second voltage provision circuits 20 and 30, respectively, and may provide the voltage switching control signal PSC to the voltage change circuit 40. Accordingly, when receiving a read command, the control circuit 60 may control the first and second voltage provision circuits 20 and 30 and the voltage change circuit 40.

For example, when the command CMD is a read command, the control circuit 60 may provide the first and second voltage provision circuits 20 and 30 with the first voltage level control signal C_vsa that enables the first read operation voltage V_pr to be output as the first voltage V_p and the second voltage level control signal C_vsb that enables the second read operation voltage V_nr to be output as the second voltage V_n, respectively, so that a forward read operation can be performed. Furthermore, the control circuit 60 may provide the voltage change circuit 40 with the voltage switching control signal PSC that enables the first read operation voltage V_pr to be provided to the global bit line GBL and that enables the second read operation voltage V_nr to be provided to the global word line GWL. At this time, after the start of a forward read operation, when the voltage level of the second voltage line V_slb is higher than the level of the reference voltage Vref, the sense amplifier 50 may output the sensing result SR (e.g., a high level) indicating that the memory cell MC has been turned on. Furthermore, after the start of a forward read operation, when the voltage level of the second voltage line V_slb is lower than the level of the reference voltage Vref, the sense amplifier 50 may output the sensing result SR (e.g., a low level) indicating that the memory cell MC has not been turned on. Accordingly, the forward read operation may be an operation that is performed in the state in which the voltage level of the bit line BL has been higher than the voltage level of the word line WL by applying a voltage having a higher level than the voltage of the global word line GWL to the global bit line GBL.

If the results of the forward read operation, that is, the sensing result SR of the sense amplifier 50, includes information indicating that the memory cell MC has been turned on, the control circuit 60 may determine the memory cell MC to be in the set state SET.

If the results of the forward read operation, that is, the sensing result SR of the sense amplifier 50, includes information indicating that the memory cell MC has not been turned on, the control circuit 60 may change the voltage switching control signal PSC so that a reverse read operation is performed. At this time, the control circuit 60 might not change the first voltage level control signal C_vsa and the second voltage level control signal C_vsb.

The voltage switching control signal PSC may be changed in the state in which the first and second voltage level control signals C_vsa and C_vsb remain intact. The changed voltage switching control signal PSC may be provided to the voltage change circuit 60.

Based on the changed voltage switching control signal PSC, the voltage change circuit 60 may provide the first read operation voltage V_pr to the global word line GWL as the first voltage V_p, and may provide the second read operation voltage V_nr to the global bit line GBL as the second voltage V_n. Accordingly, a current after the start of a reverse read operation may flow in a direction opposite to the direction of a current after the start of a forward read operation when the memory cell MC is turned on. At this time, after the start of the reverse read operation, when the voltage level of the second voltage line V_slb is lower than the level of the reference voltage Vref, the sense amplifier 50 may output the sensing result SR (e.g., a low level) indicating that the memory cell MC has been turned on. Furthermore, after the start of the reverse read operation, when the voltage level of the second voltage line V_slb is higher than the level of the reference voltage Vref, the sense amplifier 50 may output the sensing result SR (e.g., a high level) indicating that the memory cell MC has not been turned on. Accordingly, the reverse read operation may be an operation that is performed in the state in which the voltage level of the word line WL has been higher than the voltage level of the bit line BL by applying a voltage having a higher level than the voltage of the global bit line GBL to the global word line GWL.

If the results of the reverse read operation, that is, the sensing result SR of the sense amplifier 50, includes information indicating that the memory cell MC has not been turned on, the control circuit 60 may determine the memory cell MC to be in the set state SET. Furthermore, if the results of the reverse read operation, that is, the sensing result SR of the sense amplifier 50, includes information indicating that the memory cell MC has been turned on, the control circuit 60 may determine the memory cell MC to be in the reset state RST.

According to an embodiment, the control circuit 60 of the memory device may be configured to provide a forward compensation pulse to the memory cell MC that has been determined to be in the set state SET through a forward read operation and a reverse read operation. Furthermore, according to an embodiment, the control circuit 60 of the memory device may be configured to provide a reverse compensation pulse to the memory cell MC that has been determined to be in the reset state RST through a forward read operation and a reverse read operation. Furthermore, the control circuit 60 may be configured to provide a forward compensation pulse to the memory cell MC, which has been determined to be in the set state SET, and a reverse compensation pulse to the memory cell MC, which has been determined to be in the reset state RST, through a forward read operation and a reverse read operation.

When a forward compensation pulse is provided to the memory cell MC that has been determined to be in the set state SET through a forward read operation and a reverse read operation, the control circuit 60 may control the first voltage provision circuit 20 so that the first compensation operation voltage V_pc is output as the first voltage V_p and control the second voltage provision circuit 30 so that the second compensation operation voltage V_nc is output as the second voltage V_n, by changing the first and second voltage level control signals C_vsa and C_vsb, respectively. In this case, the voltage change circuit 40 may be controlled by the control circuit 60 through the voltage switching control signal PSC so that the voltage change circuit 40 provides the first compensation operation voltage V_pc to the global bit line GBL as the first voltage V_p and provides the second compensation operation voltage V_nc to the global word line GWL as the second voltage V_n. Accordingly, an operation of providing a forward compensation pulse may include an operation of providing the bit line BL with a voltage having a higher level than the voltage of the word line WL.

When the control circuit 60 provides a reverse compensation pulse to the memory cell MC that has been determined to be in the reset state RST through a forward read operation and a reverse read operation, the control circuit 60 may control the first voltage provision circuit 20 so that the first compensation operation voltage V_pc is output as the first voltage V_p, and may control the second voltage provision circuit 30 so that the second compensation operation voltage V_nc is output as the second voltage V_n. In this case, the voltage change circuit 40 may be controlled by the control circuit 60 through the voltage switching control signal PSC so that the voltage change circuit 40 provides the first compensation operation voltage V_pc to the global word line GWL as the first voltage V_p and provides the second compensation operation voltage V_nc to the global bit line GBL as the second voltage V_n. Accordingly, an operation of providing a reverse compensation pulse may include an operation of providing the word line WL with a voltage having a higher level than the voltage of the bit line BL.

Furthermore, according to an embodiment, the control circuit 60 may be configured to perform a forward read operation after providing a forward compensation pulse to the memory cell MC that has been determined to be in the set state SET through a forward read operation and a reverse read operation.

If the results of a forward read operation that has been performed again after providing a forward compensation pulse to the memory cell MC that has been determined to be in the set state SET through a forward read operation and a reverse read operation include information indicating that the memory cell MC has not been turned on, the control circuit 60 may determine the memory cell MC to be a failed memory cell, and may perform a redundancy operation of substituting the memory cell MC with another memory cell.

If the results of the forward read operation that has been performed again include information indicating that the memory cell MC has been turned on, the control circuit 60 may terminate an operation according to a read command.

As a result, the first voltage provision circuit 20, the second voltage provision circuit 30, and the voltage change circuit 40 may provide the bit line BL and the word line WL with the first and second voltages V_p and V_n through the global bit line GBL and the global word line GWL, after the start of a forward read operation, after the start of a reverse read operation, and when providing the memory cell MC with a forward compensation pulse and a reverse compensation pulse under the control of the control circuit 60. Accordingly, the first voltage provision circuit 20, the second voltage provision circuit 30, and the voltage change circuit 40 may be named a voltage supply circuit 70.

As described above, the memory device and the operating method of the memory device according to embodiments of the present disclosure can determine the state of a memory cell more accurately by performing a reverse read operation based on the results of a forward read operation when receiving a read command. Furthermore, the memory device and the operating method of the memory device according to embodiments of the present disclosure can improve the data storage reliability of a memory cell by providing the memory cell with a forward compensation pulse or a reverse compensation pulse based on the results of a reverse read operation after performing a forward read operation and the reverse read operation that are continuously performed. Furthermore, the memory device and the operating method of the memory device according to embodiments of the present disclosure can confirm a failed memory cell by consecutively performing a forward read operation and a reverse read operation, providing a memory cell with a forward compensation pulse, and then performing a forward read operation again.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. A method for operating a memory device, the method comprising:
receiving a first read command;
performing a first forward read operation for a first memory cell based on the first read command;
performing a first reverse read operation if the first memory cell has not been turned on after the first forward read operation; and
providing a forward compensation pulse to the first memory cell if the first memory cell has not been turned on after the first reverse read operation.

2. The method of claim 1, further comprising:
determining the first memory cell is in a set state if the first memory cell is determined not to be turned on after performing the first reverse read operation,
wherein the first reverse read operation and the first forward read operation are operations used to check whether the first memory cell has been turned on.

3. The method of claim 2, wherein a direction of current flow through the first memory cell when the first memory cell is turned on as a result of the first reverse read operation is opposite to a direction of current flow through the first memory cell when the first memory cell is turned on as a result of the first forward read operation.

4. The method of claim 3, wherein:
the first memory cell is electrically coupled between a bit line and a word line,
the first forward read operation includes providing the bit line with a voltage having a higher level than a voltage of the word line, and
the first reverse read operation includes providing the word line with a voltage having a higher level than a voltage of the bit line.

5. The method of claim 1, wherein:
the first memory cell is electrically coupled between a bit line and a word line, and
the providing of the forward compensation pulse comprises lowering a threshold voltage level of the first memory cell by providing the bit line with a voltage having a higher level than a voltage of the word line.

6. The method of claim 5, further comprising performing a second forward read operation on the first memory cell after providing the forward compensation pulse.

7. The method of claim 6, further comprising performing a redundancy operation of substituting the first memory cell with a different memory cell if the first memory cell has not been turned on after the second forward read operation.

8. The method of claim 1, further comprising:
receiving a second read command;
performing a second forward read operation for a second memory cell based on the second read command; and
determining whether the second memory cell has been turned on after the second forward read operation.

9. The method of claim 1, further comprising:
receiving a third read command;
performing a third forward read operation for a third memory cell based on the third read command;
performing a second reverse read operation if the third memory cell has not been turned on after the third forward read operation; determining the third memory cell is in a reset state if the third memory cell has been turned on after performing the second reverse read operation; and
providing a reverse compensation pulse to the third memory cell if the third memory cell is determined to be in the reset state.

10. The method of claim 9, wherein:
the third memory cell is electrically coupled between a bit line and a word line, and
the providing of the reverse compensation pulse comprises increasing a threshold voltage level of the third memory cell by applying the word line with a higher voltage than that applied to the bit line.

11. A memory device comprising:
a memory cell electrically coupled between a bit line and a word line;
a voltage supply circuit configured to provide a first voltage to one of the bit line and the word line and to provide a second voltage to the other of the bit line and the word line;
a sense amplifier configured to generate a sensing result by detecting whether the memory cell has been turned on; and
a control circuit configured to perform a forward read operation on the memory cell by controlling the voltage supply circuit when receiving a read command, perform a reverse read operation on the memory cell by controlling the voltage supply circuit based on a sensing result of the forward read operation, and provide the memory cell with a forward compensation pulse or a reverse compensation pulse by controlling the voltage supply circuit based on a sensing result of the reverse read operation.

12. The memory device of claim 11, wherein the first voltage has a higher magnitude than the second voltage.

13. The memory device of claim 12, wherein:
the forward read operation comprises providing the bit line with a higher voltage than that applied to the word line, and
the reverse read operation comprises providing the word line with a higher voltage than that applied to the bit line.

14. The memory device of claim 13, wherein the control circuit
provides the first voltage to the bit line and the second voltage to the word line by controlling the voltage supply circuit in order to perform the forward read operation, and
provides the first voltage to the word line and the second voltage to the bit line by controlling the voltage supply circuit in order to perform the reverse read operation.

15. The memory device of claim 14, wherein the control circuit
determines the memory cell is in a set state if the memory cell has been turned on based on the sensing result of the forward read operation, and
controls the voltage supply circuit to perform the reverse read operation if the memory cell has not been turned on based on the sensing result of the forward read operation.

16. The memory device of claim 15, wherein the control circuit
determines the memory cell is in a reset state if the memory cell has been turned on based on the sensing result of the reverse read operation, and
determines the memory cell is in the set state if the memory cell has not been turned on based on the sensing result of the reverse read operation.

17. The memory device of claim 16, wherein the control circuit
provides the forward compensation pulse to the memory cell determined to be in the set state after the reverse read operation, and
provides the reverse compensation pulse to the memory cell determined to be in the reset state after the reverse read operation.

18. The memory device of claim 17, wherein the control circuit
applies a higher voltage to the bit line than that applied to the word line by controlling the voltage supply circuit to provide the forward compensation pulse to the memory cell, and
applies a higher voltage to the word line than that applied to the bit line by controlling the voltage supply circuit to provide the reverse compensation pulse to the memory cell.

19. The memory device of claim 18, wherein:
the forward compensation pulse lowers a threshold voltage level of the memory cell by applying the first voltage to the bit line and the second voltage to the word line, and
the reverse compensation pulse raises the threshold voltage level of the memory cell by applying the first voltage to the word line and the second voltage to the bit line.

20. The memory device of claim 19, wherein the control circuit performs the forward read operation on the memory cell after applying the forward compensation pulse to the memory cell by controlling the voltage supply circuit.

21. The memory device of claim 18, wherein the control circuit performs a redundancy operation of substituting the memory cell with a different memory cell if the memory cell has not been turned on based on a sensing result of the forward read operation for the memory cell to which the forward compensation pulse has been provided.

22. The memory device of claim 12, wherein:
a global bit line is electrically coupled to the bit line,
a global word line is electrically coupled to the word line, and
the voltage supply circuit comprises a voltage change circuit configured to provide the first voltage to the global bit line and the second voltage to the global word line after the start of the forward read operation under a control of the control circuit and to provide the first voltage to the global word line and the second voltage to the global bit line after the start of the reverse read operation under the control of the control circuit.

23. The memory device of claim 22, wherein the voltage supply circuit further comprises:
a first voltage provision circuit configured to output the first voltage as the first read operation voltage after the start of the forward read operation and the reverse read operation under the control of the control circuit and to output the first voltage as the first compensation operation voltage to provide the forward compensation pulse and the reverse compensation pulse to the memory cell, and
a second voltage provision circuit configured to output as the second voltage as the second read operation voltage after the start of the forward read operation and the reverse read operation under the control of the control circuit and to output as the second voltage as the second compensation operation voltage to provide the forward compensation pulse and the reverse compensation pulse to the memory cell.

24. The memory device of claim 23, wherein a difference between the first compensation operation voltage and the second compensation operation voltage is greater than or equal to a difference between the first read operation voltage and the second read operation voltage.

25. A method for operating a memory device, the method comprising:
performing a read operation on a memory cell;
determining whether the memory cell is in a first state or a second state based on the read operation;
performing a verification operation to detect threshold voltage drift in the memory cell; and
applying a compensation pulse to adjust the threshold voltage based on the detected drift.

26. The method of claim 25, wherein the first state is a SET state and the second state is a RESET state.

27. The method of claim 26, wherein a forward compensation pulse is applied to lower the threshold voltage of the memory cell if the memory cell is in the first state, and
wherein a reverse compensation pulse is applied to raise the threshold voltage if the memory cell is in the second state.
